(19) United States
(12) Patent Application Publication
(10) Pub. No.: US 2008/0297174 A1
(43) Pub. Date: Dec. 4, 2008

(54) Capacitive sensing devices

(76) Inventors: Sarangan Narasimhan, Santa Clara, CA (US); Leonard Ye, San Jose, CA (US)

Correspondence Address: SYNAPTICS C/O WAGNER BLECHER LLP, 123 WESTRIDGE DRIVE, WATSONVILLE, CA, 95076, US

(21) Appl. No.: 11/809,566

(22) Filed: May 31, 2007

(51) Int. Cl. G06F 3/044; G01R 27/26

(52) U.S. Cl. 324/663; 345/173

(57) ABSTRACT

A capacitive sensing device comprises a set of sensing elements disposed in a two-dimensional arrangement. The two-dimensional arrangement is comprised of full elements and partial elements. A plurality of the partial elements are proximate at least one edge of the two-dimensional arrangement. Additionally, a partial element of the partial elements is smaller in element area than a full element of the full elements. An edge electrode trace of the capacitive sensing device is comprised of a selectively coupled plurality of the partial elements. The selectively coupled plurality of the partial elements resides proximate a first edge of the two-dimensional arrangement.

### BACKGROUND

Capacitive sensing devices, otherwise known as touch sensing devices or proximity sensors are widely used in modern electronic devices. A capacitive sensing device is often used for touch based navigation, selection, or other input, in response to a finger, stylus, or other object being placed on or in proximity to a sensor of the capacitive sensing device. In such a capacity, capacitive sensing devices are often employed in computers (e.g. notebook/laptop computers), media players, multi-media devices, remote controls, personal digital assistants, smart devices, telephones, and the like.

One issue that arises, often in smaller electronic devices, is that only a small area is allocated for the location of a capacitive sensing device and its sensor. Thus, in many devices and applications space is at a premium. As such, sensor designs which efficiently utilize the space allocated for capacitive sensing devices are desirable.

### SUMMARY

A capacitive sensing device comprises a set of sensing elements disposed in a two-dimensional arrangement. The two-dimensional arrangement is comprised of full elements and partial elements. A plurality of the partial elements are proximate at least one edge of the two-dimensional arrangement. Additionally, a partial element of the partial elements is smaller in element area than a full element of the full elements. An edge electrode trace of the capacitive sensing device is comprised of a selectively coupled plurality of the partial elements. The selectively coupled plurality of the partial elements resides proximate a first edge of the two-dimensional arrangement.

### BRIEF DESCRIPTION OF THE DRAWINGS

The accompanying drawings, which are incorporated in and form a part of this specification, illustrate embodiments of the technology for capacitive sensing devices and, together with the description, serve to explain principles discussed below:

FIG. 1 is a plan view of a sensor of a capacitive sensing device according to the conventional art.

FIG. 2 is a plan view of a sensor of a capacitive sensing device, according to one embodiment.

FIG. 3 shows a finger above a side view of a capacitive sensing device configured with a sensor, according to an embodiment.

FIG. 4 shows an electronic device configured with a capacitive sensing device, according to an embodiment.

FIG. 5 is a flow diagram of a method of edge electrode trace formation in a two-dimensional capacitive sensing device, according to an embodiment.

The drawings referred to in this description should not be understood as being drawn to scale unless specifically noted.

### DETAILED DESCRIPTION

Reference will now be made in detail to embodiments of the presented technology, examples of which are illustrated in the accompanying drawings. While the presented technology will be described in conjunction with embodiments, it will be understood that they are not intended to limit the presented technology to these embodiments. On the contrary, the presented technology is intended to cover alternatives, modifications and equivalents, which may be included within the spirit and scope of the presented technology as defined by the appended claims. Furthermore, in the following detailed description, numerous specific details are set forth in order to provide a thorough understanding of the presented technology. However, it will be obvious to one of ordinary skill in the art that the presented technology may be practiced without these specific details. In other instances, well known methods, procedures, components, and circuits have not been described in detail as not to unnecessarily obscure aspects of the presented technology.

### Overview of Discussion

Discussion will begin with a description of a conventional sensor of a capacitive sensing device. A modified sensor for a capacitive sensing device will then be described. Discussion will then be directed toward some example implementations of capacitive sensing devices which utilize the modified sensor. Major differences between the modified sensor and a conventional sensor will be discussed. Finally, the modified sensor for a capacitive sensing device will be further described in conjunction with description of a method for edge trace formation in a two-dimensional capacitive sensing device.

### Conventional Sensor

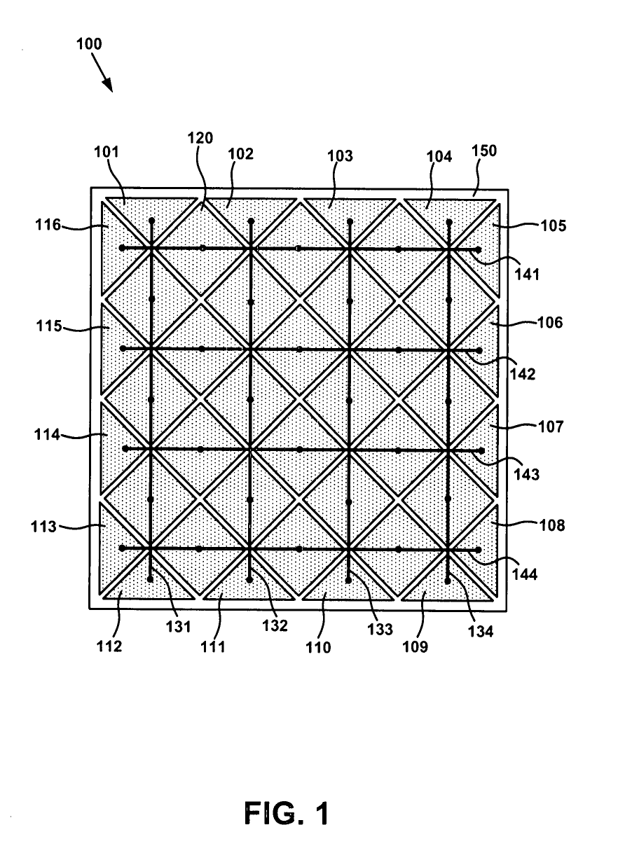

FIG. 1 is a plan view of a sensor 100 of a capacitive sensing device according to the conventional art. As shown in FIG. 1, sensor 100 is comprised of a plurality of full elements, such as element 120, and a plurality of partial elements, such as half elements 101, 102, 103, 104, 105, 106, 107, 108, 109, 110, 111, 112, 113, 114, 115, and 116, which are disposed in a two-dimensional arrangement upon a substrate 150. These partial elements (101-116) are arranged proximate to at least one edge of sensor 100. For example, with respect to the displayed orientation, partial elements 101-104 are proximate the top edge of sensor 100, partial elements 105-108 are proximate the right edge of sensor 100, partial elements 109-112 are proximate the bottom edge of sensor 100, and partial elements 113-116 are proximate the left edge of sensor 100.

Though the elements of sensor 100 are shown as diamond shapes (e.g. element 120) and half diamond shapes (e.g., element 101), it is appreciated that many other repeating shapes could be used in a similar fashion as the elements of a sensor. It is appreciated that in sensors such as sensor 100, a partial element, such as partial element 101, has an element area of less than the element area of any full element (e.g., element 120). Further, as can be seen in the conventional sensor displayed in FIG. 1, the element area of partial element 101 is approximately 50% of the element area of any full element, such as element 120. While this relationship is not required to be the case, it is typical.

The elements of sensor 100 are coupled together to form individual vertical electrode traces (131, 132, 133, 134) and individual horizontal electrode traces (141, 142, 143, 144), which are disposed in a two-dimensional pattern of electrode traces. As shown, this conventional method for coupling elements into electrode traces couples a partial element to each end of an electrode trace, with full elements being coupled to the middle section of an electrode trace. For example, horizontal electrode trace 141 is comprised of partial element 116 on the left end, three full elements in the middle, and partial electrode trace 105 on the right end. Additionally, as can be seen in FIG. 1, each electrode trace of sensor 100 comprises an electrode trace area of approximately four elements (two half elements and three full elements).

### Modified Sensor

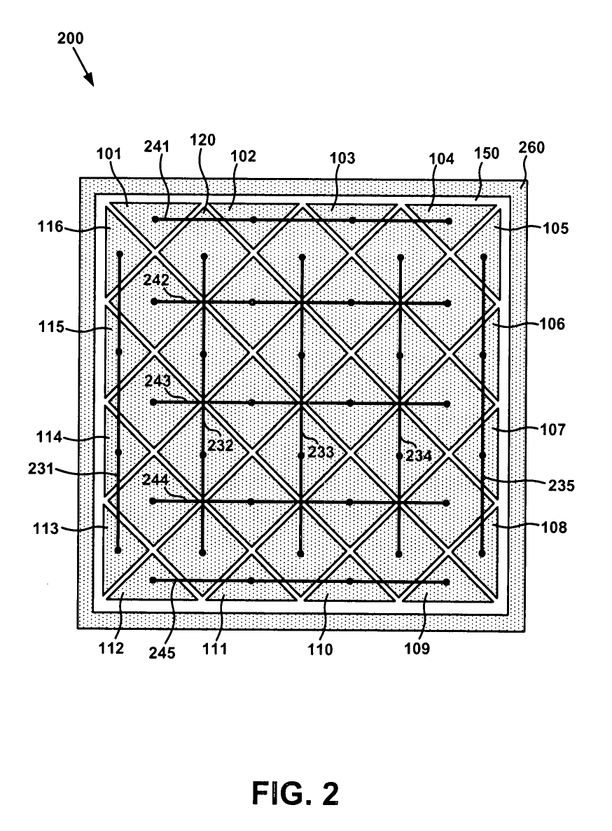

FIG. 2 is a plan view of an example sensor 200 of a capacitive sensing device, according to one embodiment. In FIG. 2, like numerals indicate like items to those of FIG. 1. As can be seen, sensor 200 is comprised of a set of sensing elements disposed in a two-dimensional arrangement which is the same as the two dimensional arrangement of conventional sensor 100. In sensor 200, the arrangement is comprised of full elements (e.g., element 120) and partial elements (e.g., elements 101-116). In sensor 200, full elements are formed in a square, or diamond shape, while partial elements are formed in a half-diamond or triangular shape. However, it is appreciated that in other embodiments, full and partial sensors can comprise other shapes such as, for example, rectangular shapes or L-shapes. Thus, it is appreciated that the concepts disclosed herein also hold true and are applicable to a wide variety of regular and irregular full and partial sensor shapes.

In FIG. 2, as in FIG. 1, a plurality of the partial elements are proximate at least one edge of the two-dimensional arrangement. For example, as shown in FIG. 2, partial elements (101-116) are arranged proximate to at least one edge of sensor 200. For example, with respect to the displayed orientation, partial elements 101-104 are proximate the top edge of sensor 200, partial elements 105-108 are proximate the right edge of sensor 200, partial elements 109-112 are proximate the bottom edge of sensor 200, and partial elements 113-116 are proximate the left edge of sensor 200. As can be seen, the full elements (e.g., element 120) are substantially the same in element area, and any partial element (e.g., element 101) of the partial elements (101-116) is smaller in element area than any full element (e.g., element 120) of the full elements. Additionally, as demonstrated by the displayed embodiment, any partial element (101-116) comprises an element area of approximately 50% of the element area of a full element (e.g. element 120).

As can be seen, in FIG. 2, an edge electrode trace (e.g., edge electrode trace 241) is comprised of a selectively coupled plurality of the partial elements (e.g., partial elements 101-104). The selectively coupled plurality of partial elements reside proximate a first edge (the top edge) of the two-dimensional arrangement of elements shown in FIG. 2. As shown in FIG. 2, in one embodiment, edge electrode trace 241 is comprised exclusively of partial elements. Additionally, as shown in FIG. 2, in one embodiment each partial electrode of such an edge electrode trace has an element size of approximately 50% of the element size of any full element (e.g., element 120). Moreover, in one embodiment, an edge electrode trace, such as edge electrode trace 241, has an electrode area of approximately one half of the electrode area of a non-edge electrode trace (e.g. electrode trace 242).

In sensor 200, there exists at least one electrode trace comprised of a selectively coupled plurality of full elements and oriented substantially parallel to edge electrode trace 241. Electrode traces 242, 243, and 244 are each examples of an electrode trace comprised of a plurality of full elements and disposed substantially a parallel to electrode trace 241. In some embodiments, as shown by FIG. 2, some electrode traces (e.g., non-edge electrode traces 242, 243, and 244) are comprised exclusively of full elements. It is appreciated that in other embodiments, an electrode trace such as electrode trace 242 may additionally comprise one or more partial elements, typically on one or both ends, which are smaller in size than the full elements in the electrode trace.

In sensor 200, there exists at least one electrode trace comprised of a selectively coupled plurality of full elements and oriented on an axis which is divergent from the axis of orientation of edge electrode trace 241. Electrode traces 232, 233, and 234 are each examples of an electrode trace comprised of a plurality of full elements and disposed on a divergent axis from the axis of orientation of edge electrode trace 241. In the embodiment of FIG. 2, electrode traces 232, 233 and 234 are substantially perpendicular to edge electrode trace 241. In some embodiments, as shown by FIG. 2, it is appreciated that some electrode traces (e.g., non-edge electrode traces 232, 233, and 234) are comprised exclusively of full elements. It is appreciated that in other embodiments, an electrode trace such as electrode trace 232 may additionally comprise one or more partial elements, typically on one or both ends, which are smaller in size than the full elements in the electrode trace.

In one embodiment, as shown by FIG. 2, there exists a second edge electrode trace (e.g., edge electrode trace 231) comprised of a selectively coupled second plurality (113-116) of the partial elements. The second plurality of partial elements (113-116) reside proximate a second edge (in this case the left edge) of the two-dimensional arrangement of elements. As can be seen, the second plurality of partial elements (113-116) that edge electrode trace 231 is comprised of is distinct and separate from the plurality partial elements (101-104) which comprise edge electrode trace 241. In this case edge electrode trace 231 is proximate an adjacent edge to that of edge electrode trace 241. However, in some instances, such as where only two edge electrode traces exist in a sensor, a second edge electrode trace may be arranged proximate an opposite edge from edge electrode trace 241. Such an electrode trace would be located in a similar location to edge electrode trace 245.

In one embodiment, as shown by FIG. 2, there exists a third edge electrode trace (e.g., edge electrode trace 245) comprised of a selectively coupled third plurality of the partial elements (109-112). The third plurality of partial elements (109-112) reside proximate a third edge (in this case the bottom edge) of the two-dimensional arrangement of elements. As can be seen, the third plurality of partial elements (109-112) that edge electrode trace 245 is comprised of is distinct and separate from the plurality partial elements (101-104) which comprise edge electrode trace 241, and is also distinct and separate from the plurality of partial elements (109-112) which comprise edge electrode trace 231. In this case edge electrode trace 245 is proximate an opposite edge to that of edge electrode 241.

In one embodiment, as shown by FIG. 2, there exists a fourth edge electrode trace (e.g., edge electrode trace 235) comprised of a selectively coupled fourth plurality of the partial elements (105-108). The fourth plurality of partial elements (105-108) reside proximate a fourth edge (in this case the right edge) of the two-dimensional arrangement of elements. As can be seen, the fourth plurality of partial elements (105-108) that edge electrode trace 235 is comprised of is distinct and separate from the plurality partial elements (101-104) which comprise edge electrode trace 241, the plurality of partial elements (113-116) which comprise edge electrode trace 231, and the plurality of partial elements (109-112) which comprise edge electrode trace 245. In this case edge electrode trace 235 is proximate an adjacent edge to that of edge electrode 241.

With continued reference to FIG. 2, in some embodiments, substrate 150 is flexible, while in other embodiments substrate 150 is rigid. Additionally, in some embodiments the elements and all electrode traces of sensor 200 are formed using commonly known circuit board fabrication techniques. Thus, in one embodiment, the elements and electrode traces of sensor 200 may be formed of copper or other conductive material of a printed circuit board. Additionally, in one embodiment, a guard (e.g., guard 260) may be included in sensor 200. This guard may be on the same layer as the elements and electrode traces, or on a different layer. In one embodiment, guard 260 is included to reduce fringe fields which corrupt the measurement of a two-dimensional position by the electrode traces of sensor 200. In some embodiments, guard 260 also performs a shielding function.

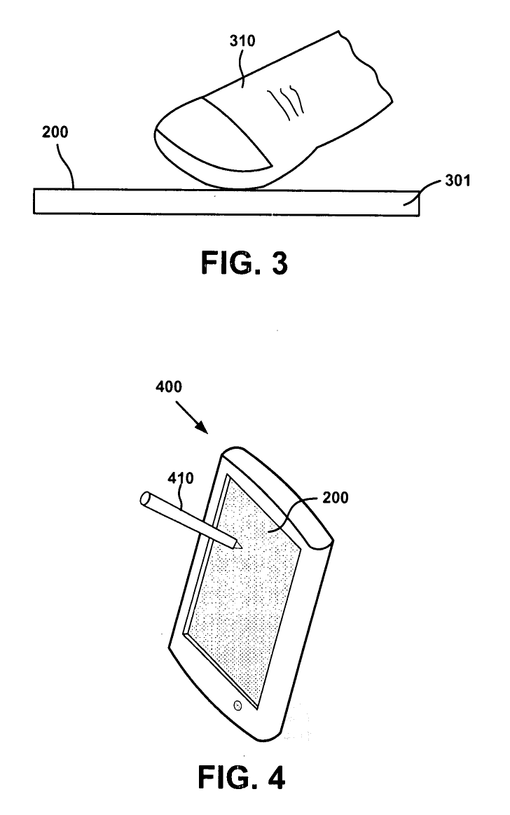

It is appreciated that in one embodiment of a capacitive sensing device, an edge electrode trace, such as edge electrode trace 241, and a plurality of additional traces (e.g., electrode traces 242, 243, 244, 232, 233, 234, and edge electrode traces 231, 235, and 245) are configured to detect a two-dimensional position of an object proximate to the capacitive sensing device. As can be seen some of these electrode traces, such as electrode traces 242, 243, 244, 232, 233, 234 are comprised of one or more full electrodes. FIG. 3 is a simplified example of an embodiment, where sensor 200 is in a capacitive sensing device.

FIG. 3 shows a finger 310 above a side view of a capacitive sensing device 301 which is configured with a sensor 200, according to an embodiment. As shown by FIG. 3, in one embodiment, capacitive sensor 200 is disposed on a surface of a capacitive sensing device 301 and utilized to sense the location of an object, such as finger 310, which is touching or proximate to capacitive sensor 200. It is appreciated that in some embodiments there may be a protective layer, or laminate covering sensor 200, such that finger 310 contacts the protective layer rather than sensor 200. In one embodiment sensor 200 (FIGS. 2 and 3) is utilized as the sensor of a capacitive sensing device 301 configured as a two-dimensional object sensing input for an electronic device. FIG. 4 shows one example of such an embodiment.

FIG. 4 shows an electronic device 400 configured with a capacitive sensing device, according to an embodiment. The capacitive sensing device utilizes an embodiment of sensor 200. Sensor 200 is used to sense a two-dimensional location of an object, such as stylus 410, with respect to the surface of sensor 200. It is appreciated that sensor 200, as shown in FIG. 2, has been presented as an example for purposes of demonstrating formation of electrode traces which comprise a modified sensor. As such, other sensors which utilize an electrode trace arrangement as demonstrated by sensor 200 may comprise a greater or lesser number of elements (including more or fewer full elements and more or fewer partial elements). As shown by the embodiment of FIG. 4, in one embodiment, sensor 200, and its corresponding sensing elements, is formed of a substantially transparent material. Itanium Tin Oxide (ITO) is one example of such a material. This is useful, for example, when capacitive sensor 200 is located on a display, such as a computer display or the display of a personal digital assistant, telephone, smart device, media player, or multi-media device.

Although only a single electronic device is shown in FIG. 4, it is appreciated that in various embodiments, capacitive sensor 200 is used as a sensor of a capacitive sensing device which includes a coupling to any of a wide variety of electronic devices. Some examples of such electronic devices include: a telephone (e.g., a cellular telephone), a computer (e.g. a desktop, laptop, notebook, tablet or small hand-holdable portable computer), a media player, a personal digital assistant, a handheld multi-media device, a keyboard, and a remote control.

### Some Major Differences from Conventional Art

One difference between sensor 100 and sensor 200 is in the manner in which electrodes are formed by coupling together the elements of the two-dimensional arrangement of elements. As shown in FIG. 1, the conventional method for coupling elements into electrodes results in four electrodes per axis being formed from the two-dimensional arrangement of elements, whereas the method for electrode formation which is described herein utilizes the same elements and the same two-dimensional arrangement of elements shown in sensor 100, but yields five electrodes per axis. In small capacitive sensing devices, such as touch pads, this helps in improving the resolution as well as the output of an algorithm utilized to locate an object such as finger.

Additionally, for an identically sized two-dimensional arrangement the mean center location of electrodes traces is pushed further outward toward the edges, as compared to the electrode traces of conventional sensor 100 of FIG. 1. This results in the ability to more accurately sense objects located near the edge of sensor 200 as compared to sensor 100. This also results in a more efficient use of area allocated for sensing, as sensor 200, being identically sized and using the same elements as sensor 100, is able to sense inputs in an increased effective sensing area. Moreover, electrode traces (e.g., electrode traces 232, 233, 234, 242, 243, 244) in the central region of sensor 200 utilize only full elements, as opposed to the combination of half and full elements of electrode traces (e.g., electrode traces 131-134 and 141-144) in the central region of sensor 100. Because of this, sensor 200 yields a central region with greater linear sensitivity to objects (e.g., a finger or a stylus) than that of sensor 100.

### Method for Edge Trace Formation

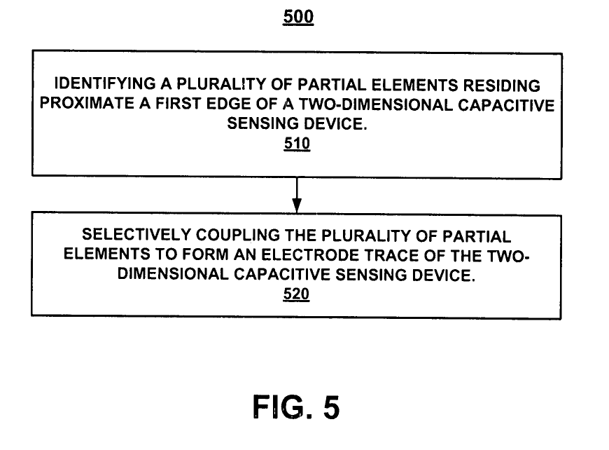

FIG. 5 is a flow diagram 500 of a method, according to one embodiment, of edge electrode trace formation in a two-dimensional capacitive sensing device comprised of full elements (e.g., 120) and partial elements (e.g., 101-116) which are smaller in element size than the full elements. In the description of flow diagram 500, reference will be made to sensor 200 of FIG. 2, which provides one example of a portion of a capacitive sensing device which may be produced according to the method of flow diagram 500. Although specific steps are disclosed and described in conjunction with flow diagram 500, such steps are examples. That is, the embodiments of the present technology are well-suited to performing various other steps or variations of the steps recited in flow diagram 500. It is appreciated that the steps in flow diagram 500 may be performed in an order different than presented and that the steps in flow diagram 500 are not necessarily performed in the sequence illustrated. In addition, in some embodiments one or more of the steps of flow diagram 500 may be performed manually.

With reference to FIG. 5, in 510, in one embodiment, the method identifies a plurality of the partial elements residing proximate a first edge of the two-dimensional capacitive sensing device. For example, with reference to FIG. 2, in one embodiment, this comprises identifying partial elements 101-104 residing proximate a top edge of sensor 200.

In 520, in one embodiment, the method selectively couples the identified plurality of the partial elements (e.g. 101-104) to form an electrode trace of the two-dimensional capacitive sensing device. As can be seen, in one embodiment an electrode trace, such as edge electrode trace 241, is formed by this selective coupling of elements. As demonstrated by FIG. 2, in one embodiment, an edge electrode trace, such as edge electrode trace 241, is comprised exclusively of partial electrodes.

In one embodiment, the method illustrated by flow diagram 500 also comprises, identifying a second plurality of the partial elements (e.g., 113-116) residing proximate a second edge (e.g., the left edge) of the two-dimensional capacitive sensing device. This second plurality of partial elements (e.g., 113-116) is selectively coupled to form a second electrode trace (e.g., edge electrode trace 231) of the two-dimensional capacitive sensing device. In one instance, as illustrated in FIG. 2 by edge electrode trace 231, a second electrode trace is comprised of a plurality of partial elements residing proximate an adjacent edge to the first edge. In another instance, as illustrated in FIG. 2 by edge electrode trace 245, a second electrode trace is comprised of a plurality of partial elements (109-112) residing proximate an opposing edge of the capacitive sensing device, wherein the opposing edge is substantially parallel to the first edge.

In one embodiment, the method illustrated by flow diagram 500 also comprises, identifying a third plurality of the partial elements (e.g., 109-112) residing proximate a third edge (e.g., the bottom edge) of the two-dimensional capacitive sensing device. This third plurality of partial elements (e.g., 109-112) is selectively coupled to form a third electrode trace (e.g., edge electrode trace 245) of the two-dimensional capacitive sensing device.

In one embodiment, the method illustrated by flow diagram 500 also comprises, identifying a fourth plurality of the partial elements (e.g., 105-108) residing proximate a fourth edge (e.g., the right edge) of the two-dimensional capacitive sensing device. This fourth plurality of partial elements (e.g., 105-108) is selectively coupled to form a fourth electrode trace (e.g., edge electrode trace 235) of the two-dimensional capacitive sensing device.

Moreover, in one embodiment, the method illustrated by flow diagram 500 also comprises forming at least one electrode trace to include a full element of the previously described full elements. Electrode traces 232, 233, 234, 242, 243, and 244 provide examples of non-edge electrode traces formed to include at least one full element. These electrode traces further provide example of electrode traces, which in some embodiments, are formed to comprise exclusively full elements.

The foregoing descriptions of specific embodiments have been presented for purposes of illustration and description. They are not intended to be exhaustive or to limit the presented technology to the precise forms disclosed, and obviously many modifications and variations are possible in light of the above teaching. The embodiments were chosen and described in order to best explain the principles of the presented technology and its practical application, to thereby enable others skilled in the art to best utilize the presented technology and various embodiments with various modifications as are suited to the particular use contemplated. It is intended that the scope of the present technology be defined by the claims appended hereto and their equivalents.

What is claimed is:

1. A capacitive sensing device comprising:
a set of sensing elements disposed in a two-dimensional arrangement comprised of full elements and partial elements, wherein a plurality of said partial elements are proximate at least one edge of said two-dimensional arrangement, and wherein any partial element of said partial elements is smaller in element area than any full element of said full elements; and
an edge electrode trace comprised of a selectively coupled plurality of said partial elements, said selectively coupled plurality of said partial elements residing proximate a first edge of said two-dimensional arrangement.

2. The capacitive sensing device of claim 1, further comprising:
at least one electrode trace comprised of a selectively coupled plurality of said full elements and oriented substantially parallel to said edge electrode trace.

3. The capacitive sensing device of claim 1, further comprising:
at least one electrode trace comprised of a selectively coupled plurality of said full elements and oriented on an axis divergent from said edge electrode trace.

4. The capacitive sensing device of claim 1, further comprising:
a plurality of additional electrode traces, wherein an electrode trace of said plurality of additional electrode traces is comprised of a selectively coupled plurality of said full elements.

5. The capacitive sensing device of claim 4, wherein said edge electrode trace and said plurality of additional electrode traces are configured to detect a two-dimensional position of an object proximate to said capacitive sensing device.

6. The capacitive sensing device of claim 1, and wherein said full elements are substantially uniform in element area, and wherein any partial element of said partial elements comprises an element area of approximately 50% of an element area of a full element of said full elements.

7. The capacitive sensing device of claim 1, further comprising:
a second edge electrode comprised of a selectively coupled second plurality of said partial elements, said second plurality of said partial elements residing proximate a second edge of said two-dimensional arrangement.

8. The capacitive sensing device of claim 7, wherein said second plurality of said partial elements is separate from said plurality of said partial elements residing proximate said first edge.

9. The capacitive sensing device of claim 7, wherein said first edge and said second edge are adjacent edges.

10. The capacitive sensing device of claim 7, wherein said first edge and said second edge are opposite edges.

11. The capacitive sensing device of claim 7, further comprising:
a third edge electrode comprised of a selectively coupled third plurality of said partial elements, said third plurality of said partial elements residing proximate a third edge of said two-dimensional arrangement.

12. The capacitive sensing device of claim 11, wherein said third plurality of said partial elements is separate from both said second plurality of said partial elements and said plurality of said partial elements residing proximate said first edge.

13. The capacitive sensing device of claim 11, further comprising:
a fourth edge electrode comprised of a selectively coupled fourth plurality of said partial elements, said fourth plurality of said partial elements residing proximate a fourth edge of said two-dimensional arrangement.

14. The capacitive sensing device of claim 13, wherein said fourth plurality of said partial elements is separate from said third plurality of said partial elements, second plurality of said partial elements, and said plurality of said partial elements residing proximate said first edge.

15. The capacitive sensing device of claim 1, wherein said set of sensing elements is formed of a substantially transparent material.

16. The capacitive sensing device of claim 1, further comprising:
a guard layer.

17. The capacitive sensing device of claim 1, further comprising:
a flexible substrate upon which said two-dimensional arrangement is disposed.

18. The capacitive sensing device of claim 1, wherein said capacitive sensing device is configured as a two-dimensional object sensing input for an electronic device.

19. The capacitive sensing device of claim 18, further comprising:
a coupling to an electronic device selected from the list of electronic devices consisting of: a telephone, a computer, a media player, a personal digital assistant, a handheld multi-media device, a keyboard, and a remote control.

20. A method of edge electrode trace formation in a two-dimensional capacitive sensing device comprised of full elements and partial elements which are smaller in element size than said full elements, said method comprising:
identifying a plurality of said partial elements residing proximate a first edge of said two-dimensional capacitive sensing device; and
selectively coupling said plurality of partial elements to form an electrode trace of said two-dimensional capacitive sensing device.

21. The method as recited in claim 20, further comprising:
identifying a second plurality of said partial elements residing proximate a second edge of said two-dimensional capacitive sensing device; and
selectively coupling said second plurality of partial elements to form a second electrode trace of said two-dimensional capacitive sensing device.

22. The method as recited in claim 21, wherein said identifying a second plurality of partial elements residing proximate a second edge of said two-dimensional capacitive sensing device comprises:
identifying said second plurality of said partial elements residing proximate an adjacent edge to said first edge.

23. The method as recited in claim 21, wherein said identifying a second plurality of partial elements residing proximate a second edge of said two-dimensional capacitive sensing device comprises:
identifying said second plurality of said partial elements residing proximate an opposing edge to said first edge.

24. The method as recited in claim 21, further comprising:
identifying a third plurality of said partial elements residing proximate a third edge of said two-dimensional capacitive sensing device; and
selectively coupling said third plurality of said partial elements to form a third electrode trace of said two-dimensional capacitive sensing device.

25. The method as recited in claim 24, further comprising:
identifying a fourth plurality of said partial elements residing proximate a fourth edge of said two-dimensional capacitive sensing device; and
selectively coupling said fourth plurality of said partial elements to form a fourth electrode trace of said two-dimensional capacitive sensing device.

26. The method as recited in claim 20, further comprising:
forming at least one electrode trace to include a full element of said full elements.
